(19) United States
(12) Patent Application Publication
(10) Pub. No.: US 2013/0270625 A1
(43) Pub. Date: Oct. 17, 2013

(54) THREE-DIMENSIONAL SEMICONDUCTOR MEMORY DEVICES AND METHODS OF FABRICATING THE SAME

(71) Applicants: Byong-hyun JANG, Suwon-si (KR); Janggn Yun, Hwaseong-si (KR); KwangSoo Seol, Yongin-si (KR); Jungdal Choi, Hwaseong-si (KR); Byongju Kim, Seoul (KR); Kwangmin Park, Seoul (KR); Junkyu Yang, Seoul (KR); SeungHyun Lim, Seoul (KR)

(72) Inventors: Byong-hyun JANG, Suwon-si (KR); Janggn Yun, Hwaseong-si (KR); KwangSoo Seol, Yongin-si (KR); Jungdal Choi, Hwaseong-si (KR); Byongju Kim, Seoul (KR); Kwangmin Park, Seoul (KR); Junkyu Yang, Seoul (KR); SeungHyun Lim, Seoul (KR)

(21) Appl. No.: 13/838,159

(22) Filed: Mar. 15, 2013

(30) Foreign Application Priority Data
Apr. 16, 2012 (KR) 10-2012-0039154

(51) Int. Cl. H01L 29/792

(52) U.S. Cl. CPC H01L 29/7926
USPC 257/324

(57) ABSTRACT

A three-dimensional (3D) semiconductor memory device includes a stack structure, a channel structure, and a vertical insulator. The stack structure includes gate patterns and insulating patterns which are alternately and repeatedly stacked on a substrate. A channel structure penetrates the stack structure and is connected to the substrate. A vertical insulator includes a high-k dielectric layer. The vertical insulator is covered by the channel structure and the high-k dielectric pattern of the vertical insulator is in contact with the gate patterns.

### CROSS-REFERENCE TO RELATED APPLICATION

This application claims priority under 35 U.S.C. §119 to Korean Patent Application No. 10-2012-0039154, filed on Apr. 16, 2012, in the Korean Intellectual Property Office, the disclosure of which is incorporated by reference herein in its entirety.

### TECHNICAL FIELD

The inventive concept relates to semiconductor devices and methods of fabricating the same and, more particularly, to three-dimensional semiconductor memory devices having three-dimensionally arranged memory cells and methods of fabricating the same.

### DISCUSSION OF RELATED ART

Higher density of semiconductor memory devices tends to reduce manufacturing costs of semiconductor memory devices. The density of semiconductor memory devices may be determined by the area occupied by a unit memory cell. In general, reduction of such unit memory cell area demands using expensive processing equipments, which may set a practical limitation on reducing the manufacturing costs.

To overcome such a limitation, three-dimensional semiconductor memory devices having three-dimensionally arranged memory cells have been proposed.

### SUMMARY

According to an exemplary embodiment of the inventive concept, a three-dimensional (3D) semiconductor memory device includes a stack structure, a channel structure, and a vertical insulator. The stack structure includes gate patterns and insulating patterns which are alternately and repeatedly stacked on a substrate. A channel structure penetrates the stack structure and is connected to the substrate. A vertical insulator includes a high-k dielectric layer. The vertical insulator is covered by the channel structure and the high-k dielectric pattern of the vertical insulator is in contact with the gate patterns.

According to an exemplary embodiment of the inventive concept, a three-dimensional (3D) semiconductor memory device is fabricated. A thin-layer structure is formed on a substrate. The thin-layer structure includes a plurality of first material layers and a plurality of second material layers which are alternately and repeatedly stacked on the substrate. An opening is formed in the thin layer-structure, exposing the substrate. A vertical insulator is formed, covering an inner sidewall of the opening. The vertical insulator exposes the substrate under the opening. A channel structure is formed, covering an inner sidewall of the vertical insulator. The channel structure is connected to the substrate. The vertical insulator is formed by stacking sequentially a high-k dielectric layer, a blocking insulating layer, a charge storing layer, and a tunnel insulating layer on the inner sidewall of the opening.

According to an exemplary embodiment of the inventive concept, a three-dimensional (3D) semiconductor memory device is formed on a substrate. A channel structure is connected to the substrate and is extended in a direction perpendicular to the substrate. A vertical insulator including a high-k dielectric layer is disposed on the channel structure. A first metal gate pattern and a second metal gate pattern is disposed on the high-k dielectric layer of the vertical insulator. The metal gate patterns are extended in a direction parallel to the substrate and are spaced apart from each other in the direction perpendicular to the substrate.

### BRIEF DESCRIPTION OF THE DRAWINGS

These and other features of the inventive concept will become more apparent by describing in detail exemplary embodiments thereof with reference to the accompanying drawings of which:

FIG. 1 is a cell array of a three-dimensional (3D) semiconductor memory device according to an exemplary embodiment of the inventive concept;

FIG. 2 is a cross-sectional view illustrating a 3D semiconductor memory device according to an exemplary embodiment of the inventive concept;

FIG. 3 is an enlarged view of portion ‘A’ of FIG. 2;

FIG. 4 is a cross-sectional view illustrating a 3D semiconductor memory device according to an exemplary embodiment of the inventive concept;

FIG. 5 is an enlarged view of portion ‘A’ of FIG. 4;

FIGS. 6 to 14 are cross-sectional views illustrating a method of fabricating a 3D semiconductor memory device according to an exemplary embodiment of the inventive concept;

FIGS. 15 to 18 are partial cross-sectional views illustrating a method of fabricating a 3D semiconductor memory device according to an exemplary embodiment of the inventive concept;

FIGS. 19 to 26 are partial cross-sectional views illustrating a method of fabricating a 3D semiconductor memory device according to an exemplary embodiment of the inventive concept;

FIGS. 27 to 31 are partial cross-sectional views illustrating a method of fabricating a 3D semiconductor memory device according to an exemplary embodiment of the inventive concept;

FIG. 32 is a partial cross-sectional view illustrating a 3D semiconductor memory device according to an exemplary embodiment of the inventive concept;

FIG. 33 is a partial cross-sectional view illustrating a 3D semiconductor memory device according to an exemplary embodiment of the inventive concept;

FIG. 34 is a schematic block diagram illustrating an exemplary memory system including a 3D semiconductor memory device according to an exemplary embodiment of the inventive concept;

FIG. 35 is a schematic block diagram illustrating an exemplary memory card including a 3D semiconductor memory device according to an exemplary embodiment of the inventive concept; and

FIG. 36 is a schematic block diagram illustrating an exemplary information processing system including a 3D semiconductor memory device according to an exemplary embodiment of the inventive concept.

### DETAILED DESCRIPTION OF THE EMBODIMENTS

Exemplary embodiments of the inventive concept will be described below in more detail with reference to the accompanying drawings. However, the inventive concept may be embodied in different forms and should not be construed as limited to the embodiments set forth herein. (Rather, these exemplary embodiments are provided so that this disclosure will be thorough and complete and will fully convey the inventive concept to those skilled in the art.) In the drawings, the thickness of layers and regions may be exaggerated for clarity. Like reference numerals may refer to the like elements throughout the specification and drawings.

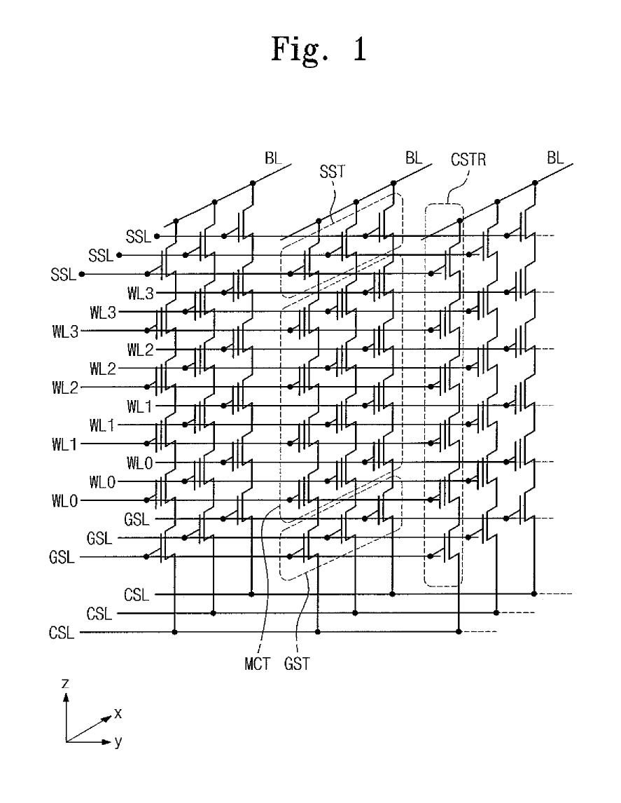

FIG. 1 is a cell array of a three-dimensional (3D) semiconductor memory device according to an exemplary embodiment of the inventive concept.

Referring to FIG. 1, a cell array of a three-dimensional (3D) semiconductor device may include a common source line CSL, a plurality of bit lines BL, and a plurality of cell strings CSTR disposed between the common source line CSL and the bit lines BL.

The bit lines BL may be two-dimensionally arranged. A plurality of the cell strings CSTR may be connected in parallel to each of the bit lines BL. The cell strings CSTR may be connected in common to the common source line CSL. For example, a plurality of the cell strings CSTR may be disposed between a plurality of the bit lines BL and the common source line CSL. The common source line CSL may be provided in a plural number and the common source lines CSL may be two-dimensionally arranged. The same voltage may be applied to the common source lines CSL. Alternatively, the common source lines CSL may be electrically controlled independently from each other.

Each of the cell strings CSTR may include a ground selection transistor GST connected to the common source line CSL, a string selection transistor SST connected to the bit line BL, and a plurality of memory cell transistors MCT between the ground and string selection transistors GST and SST. The ground selection transistor GST, the memory cell transistors MCT, and the string selection transistor SST may be connected in series to each other.

The common source line CSL may be connected in common to sources of the ground selection transistors GST. A ground selection line GSL, a plurality of word lines WL0 to WL3, a plurality of string selection lines SSL, which are disposed between the common source line CSL and the bit lines BL, may be used as gate electrodes of the ground selection transistor GST, the memory cell transistors MCT, and the string selection transistors SST, respectively. Each of the memory cell transistors MCT includes a data storage element.

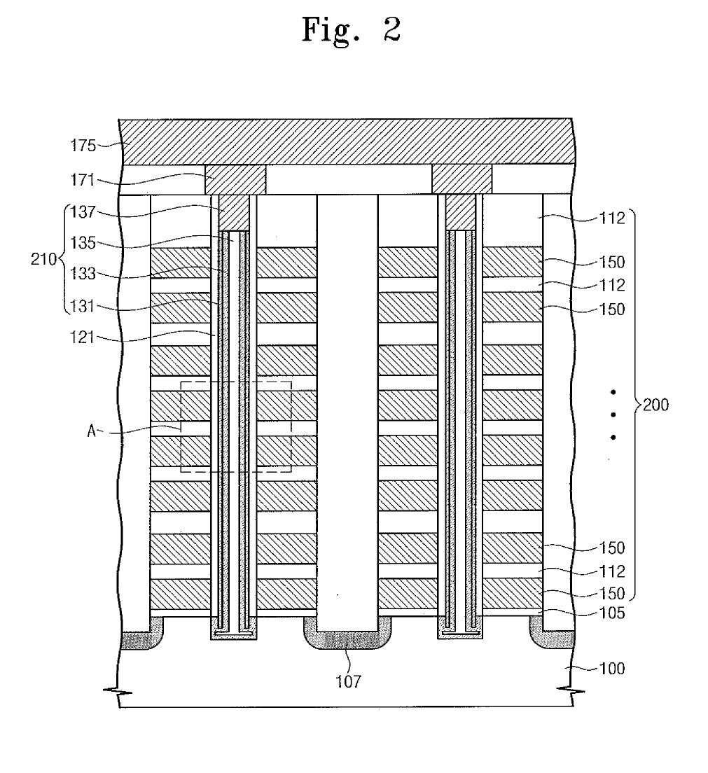

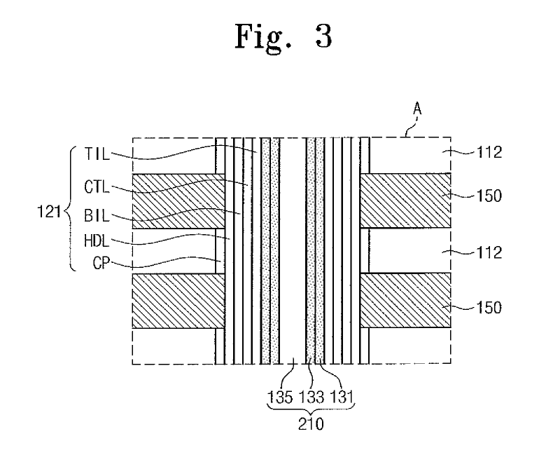

FIG. 2 is a cross-sectional view illustrating a 3D semiconductor memory device according to an exemplary embodiment of the inventive concept, and FIG. 3 is an enlarged view of portion ‘A’ of FIG. 2.

Referring to FIG. 2, a stack structure 200 is disposed on a substrate 100. The stack structure 200 may include insulating patterns 112 and gate patterns 150 which are alternately and repeatedly stacked on the substrate 100.

The substrate 100 may include a semiconductor material. For example, the substrate 100 may include a silicon substrate, a germanium substrate, and/or a silicon-germanium substrate. The substrate 100 may include a common source region 107 doped with dopants.

The stack structure 200 may have a line-shape extending in a direction perpendicular to the cross-sectional view. In an embodiment, some (e.g., an uppermost gate pattern and a lowermost gate pattern) of the gate patterns 150 may be used as gate electrodes of the ground and string selection transistors GST and SST described with reference to FIG. 1. For example, in a 3D NAND flash memory device, the uppermost gate pattern may be used as the gate electrode of the string selection transistor SST controlling electrical connection between a bit line 175 and a channel structure 210, and the lowermost gate pattern may be used as the gate electrode of the ground selection transistor GST controlling electrical connection between the common source region 107 (i.e., the common source line) and the channel structure 210.

Additionally, a lower insulating layer 105 may be formed between the substrate 100 and the stack structure 200. For example, the lower insulating layer 105 may include a silicon oxide layer formed by a thermal oxidation process. Alternatively, the lower insulating layer 105 may include a silicon oxide layer formed using a deposition technique. The lower insulating layer 105 may have a thickness less than that of the insulating patterns 112 thereon.

The channel structure 210 may penetrate the stack structure 200 and may be electrically connected to the substrate 100. The channel structure 210 may successively penetrate a plurality of the gate patterns 150 stacked on the substrate 100. For example, the channel structure 210 may include a semiconductor material. The channel structure 210 may include a conductive pad 137 disposed at a top end portion of the channel structure 210. The conductive pad 137 may include a dopant region doped with dopants. Alternatively, the conductive pad 137 may be formed of a conductive material. A bottom surface of the channel structure 210 may be disposed at a lower level than a top surface of the substrate 100. For example, a bottom end portion of the channel structure 210 may be inserted in the substrate 100.

The channel structures 210 penetrating the stack structure 200 may extend in a direction perpendicular to the cross-section view in a plan view. Alternatively, the channel structures 210 penetrating the stack structure 200 may extend in a zigzag form along the direction perpendicular to the cross-section view in a plan view.

The channel structure 210 may have a hollow pipe-shape or a hollow macaroni-shape in a cross-sectional view. At this time, a bottom end of the channel structure 210 may be closed. An internal region of the channel structure may be filled with a filling insulating pattern 135.

For example, the channel structure 210 may include a first semiconductor pattern 131 and a second semiconductor pattern 133. The first semiconductor pattern 131 may cover an inner sidewall of the stack structure 200. The first semiconductor pattern 131 may have a pipe-shape (or a macaroni-shape) of which a top end and a bottom end are open. The first semiconductor pattern 131 might not be in contact with the substrate 100. For example, the first semiconductor pattern 131 may be spaced apart from the substrate 100 by the second semiconductor pattern 131

The second semiconductor pattern 133 may have a pipe-shape (or a macaroni-shape) of which a bottom end is closed. An internal region of the second semiconductor pattern 133 may be filled with the filling insulating pattern 135. The second semiconductor pattern 133 may be in contact with an inner sidewall of the first semiconductor pattern 131 and the top surface of the substrate 100. For example, the second semiconductor pattern 133 may electrically connect the first semiconductor pattern 131 to the substrate 100.

The first and second semiconductor patterns 131 and 133 may be undoped or be doped with dopants of a same conductivity type as dopants of the substrate 100. The first semiconductor pattern 131 and the second semiconductor pattern 132 may be in a poly-crystalline state or single-crystalline state.

A vertical insulator 121 may be disposed between the stack structure 200 and the channel structure 210. The vertical insulator 121 may have a pipe-shape (or a macaroni-shape) of which a top end and a bottom end are open.

For example, a vertical length of the vertical insulator 121 may be less than a vertical length of the channel structure 210. The vertical length of the vertical insulator 121 may be smaller than a vertical length of the first semiconductor pattern 131. The second semiconductor pattern 133 may have a protruding portion laterally extending from a bottom end portion of the semiconductor pattern 133. The vertical insulator 121 and the first semiconductor pattern 131 may be disposed on the protruding portion of the second semiconductor pattern 133. In other words, the protruding portion of the second semiconductor pattern 133 may be disposed between the vertical insulator 121 and the substrate 100 and between the first semiconductor pattern 131 and the substrate 100.

The vertical insulator 121 may include a memory element of a flash memory device. For example, the vertical insulator 121 may include a charge storing layer of the flash memory device. For example, the charge storing layer may include a trap insulating layer, or an insulating layer including conductive nano dots. Logic data stored in the vertical insulator 121 may be changed using Fowler-Nordheim tunneling induced by voltage differences between the channel structure 210 and the gate patterns 150. Alternatively, the vertical insulator 121 may include a thin layer capable of storing logic data by another operation principle (e.g., a thin layer for a phase change memory element or a thin layer for a variable resistance memory element). The vertical insulator 121 will be described in more detail with reference to FIG. 3.

The bit line 175 may be disposed to cross over the stack structure 200. The bit line 175 may be electrically connected to the conductive pad 137 of the channel structure 210 through a contact plug 171.

Hereinafter, a structure of the vertical insulator of the 3D semiconductor memory device according to an exemplary embodiment will be described in more detail with reference to FIG. 3. FIG. 3 is an enlarged view of portion ‘A’ of FIG. 2.

Referring to FIG. 3, the vertical insulator 121 may include a high-k dielectric layer HDL, a blocking insulating layer BIL, a charge storing layer CTL, and a tunnel insulating layer TIL which are sequentially stacked on the inner sidewall of the stack structure 200 of FIG. 2. The inner sidewall of the stack structure 200 may include inner sidewalls of the gate patterns 150 and inner sidewalls of the insulating patterns. The high-k dielectric layer HDL may be in direct contact with the inner sidewalls of the gate patterns 150 and the insulating patterns 112. The tunnel insulating layer TIL may be in direct contact with the channel structure 210. The charge storing layer CTL may be disposed between the tunnel insulating layer TIL and the blocking insulating layer BIL, and the blocking insulating layer BIL may be disposed between the charge storing layer CTL and the high-k dielectric layer HDL.

The charge storing layer CTL may include a trap insulating layer, or an insulating layer including conductive nano dots. For example, the charge storing layer CTL may include a silicon nitride layer, a silicon oxynitride layer, a silicon-rich nitride layer, a nano-crystalline silicon layer, and/or a laminated trap layer.

The tunnel insulating layer TIL may include an insulating material having an energy band gap greater than that of the charge storing layer CTL. For example, the tunnel insulating layer TIL may include a silicon oxide layer.

The blocking insulating layer BIL may include an insulating material having an energy band gap greater than that of the charge storing layer CTL. For example, the blocking insulating layer BIL may include a silicon oxide layer.

The high-k dielectric layer HDL may be formed of a material having a dielectric constant greater than that of the blocking insulating layer BIL. For example, the high-k dielectric layer HDL may include tantalum oxide (Ta₂O₅), titanium oxide (TiO₂), hafnium oxide (HfO₂), zirconium oxide (ZrO₂), hafnium silicate (HfSixOy), zirconium silicate (ZrSixOy), hafnium silicate nitride (HfSixOyNz), zirconium silicate nitride (ZrSixOyNz), aluminum oxide (Al₂O₃), aluminum oxynitride (AlxOyNz), hafnium aluminate (HfAlxOy), yttrium oxide (Y₂O₃), niobium oxide (Nb₂O₅), cerium oxide (CeO₂), indium oxide (InO₃), lanthanum oxide (LaO₂), ((Ba,Sr)TiO₃,BST), (Pb(Zr,Ti)O₃, PZT), strontium-titanium oxide (SrTiO₃), lead-titanium oxide (PbTiO₃), strontium-ruthenium oxide (SrRuO₃), calcium-ruthenium oxide (CaRuO₃), (Pb,La)(Zr,Ti)O₃, and/or (Sr,Ca)RuO₃. The high-k dielectric layer HDL may be single-layered. Alternatively, the high-k dielectric layer HDL may have a laminated structure including stacked thin layers.

The vertical insulator 121 may include a hafnium oxide layer, a silicon oxide layer, a silicon nitride layer, and/or a silicon oxide layer which are sequentially stacked on the inner sidewall of the stack structure 200.

For example, the vertical insulator 121 may further include capping patterns CP between the high-k dielectric layer HDL and the insulating patterns 112. The capping patterns CP may be vertically separated from each other by the gate patterns 150. The capping patterns CP may include an insulating material having etch selectivity with respect to the high-k dielectric layer HDL. The capping patterns CP may include a same material as the insulating patterns 112. For example, the capping patterns CP may include a silicon layer, a silicon oxide layer, a poly-silicon layer, a silicon carbide layer, and/or a silicon nitride layer.

The gate pattern 150 may be in direct contact with the high-k dielectric layer HDL of the vertical insulator 121. Additionally, the gate pattern 150 may be in direct contact with the insulating patterns 112 vertically adjacent to the gate pattern 150. Such direct contact structure of the gate pattern 150 and the insulating patterns 112 may prevent a portion of the vertical insulator 121 from forming between the gate pattern 150 and the insulating patterns 112. As result, it is possible to reduce a vertical height of the stack structure 200 of FIG. 2. Thus, integration density of the 3D semiconductor memory device may be increased by reducing the vertical height of the stack structure 200.

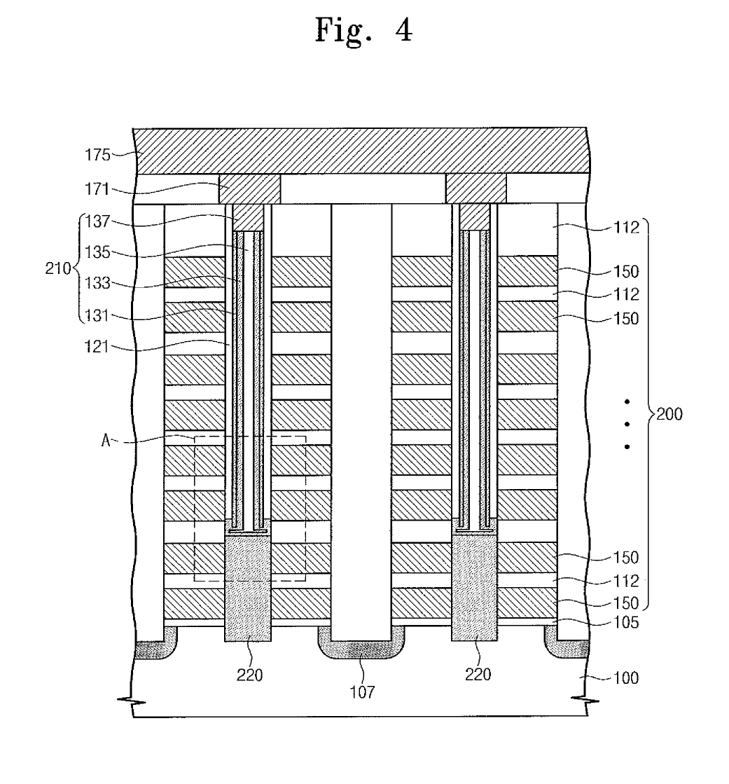

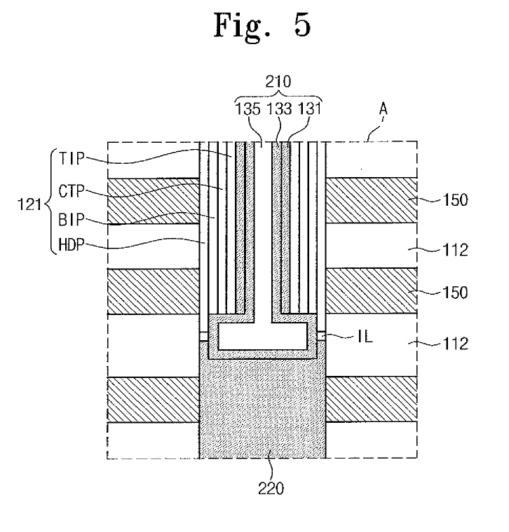

FIG. 4 is a cross-sectional view illustrating a 3D semiconductor memory device according to an exemplary embodiment of the inventive concept, and FIG. 5 is an enlarged view of a portion ‘A’ of FIG. 4.

Referring to FIG. 4, a 3D semiconductor memory device may include a semiconductor pillar 220 penetrating a lower portion of the stack structure 200 and connected to the substrate 100. A bottom surface of the semiconductor pillar 220 may be disposed to be lower than a top surface of the substrate 100. For example, a lower portion of the semiconductor pillar 220 may be buried in a recessed portion of the substrate 100.

The insulating pattern 112 and the gate pattern 150 adjacent to the semiconductor pillar 220 may be in contact with a sidewall of the semiconductor pillar 220. The vertical insulator 121 and the channel structure 210 may be disposed on a top surface of the semiconductor pillar 220. The channel structure 210 may penetrate an upper portion of the stack structure 200 and may be in contact with the semiconductor pillar 220. As described in the above embodiment, the channel structure 210 may include the first and second semiconductor patterns 131 and 133 and the filling insulating pattern 135.

Hereinafter, a structure of the vertical insulator in the 3D semiconductor memory device according to an exemplary embodiment will be described in more detail with reference to FIG. 5.

Referring to FIG. 5, the vertical insulator 121 may include a high-k dielectric pattern HDP, a blocking insulating pattern BIP, a charge storing pattern CTP, and a tunnel insulating pattern TIP.

The high-k dielectric pattern HDP may include a high-k dielectric material including hafnium (Hf). For example, the high-k dielectric pattern HDP may include hafnium oxide (HfO₂), hafnium silicate (HfSixOy), hafnium silicate nitride (HfSixOyNz), and/or hafnium aluminate (HfAlxOy).

A bottom surface of the high-k dielectric pattern HDP may be disposed to be lower than bottom surfaces of the blocking insulating pattern BIP, the charge storing pattern CTP, and the tunnel insulating pattern TIP. The second semiconductor pattern 133 may cover the bottom surfaces of the blocking insulating pattern BIP, the charge storing pattern CTP, and the tunnel insulating pattern TIP and may be in contact with a lower sidewall of the high-k dielectric pattern HDP. If the high-k dielectric pattern HDP is formed of the high-k dielectric material including hafnium (Hf), a hafnium-silicon oxide layer IL may be disposed between the high-k dielectric pattern HDP and the semiconductor pillar 220.

The vertical insulator 121 may further include capping patterns CP disposed between the high-k dielectric pattern HDP and the insulating patterns 112 as illustrated in FIG. 3.

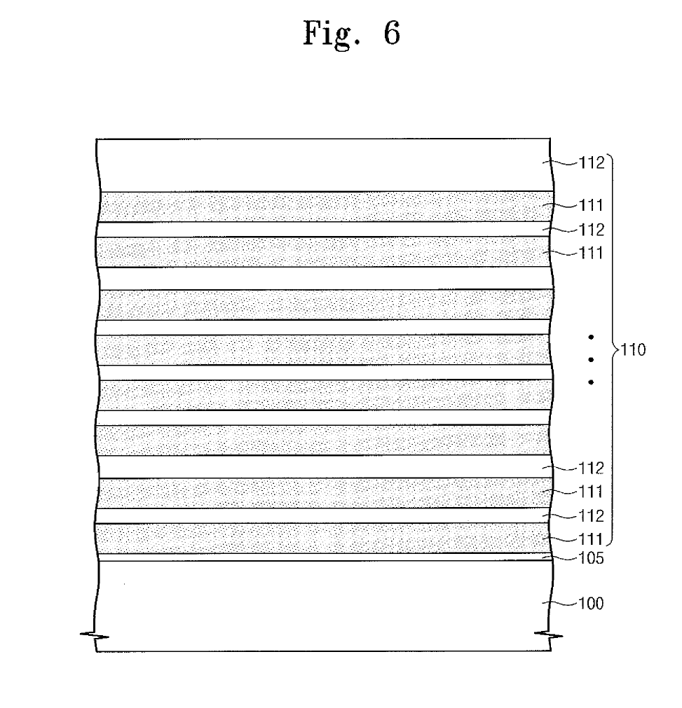

FIGS. 6 to 14 are cross-sectional views illustrating a method of fabricating a 3D semiconductor memory device according to an exemplary embodiment of the inventive concept.

Referring to FIG. 6, first material layers 111 and second material layers 112 may be alternately and repeatedly stacked on a substrate 100 to form a thin layer-structure 110.

The substrate 100 may include materials having semiconductor properties, insulating materials, a semiconductor covered by an insulating material, and a conductor. For example, the substrate 100 may include a silicon substrate, a germanium substrate, or a silicon-germanium substrate.

The first material layers 111 may include a material having etch selectivity with respect to that of the second material layers 112. For example, the first material layers 111 may have a high etch rate with respect to the second material layers 112 in a wet etching process using a chemical solution. Alternatively, the first material layers 111 may have a high etch rate with respect to the second material layers 112 in a dry etching process using an etching gas. A thickness of the first material layer 111 may be equal to a thickness of the second material layer 112. Alternatively, the thickness of the first material layer 111 may be different from the thickness of the second material layer 112.

The first and second material layers 111 and 112 may be deposited using a thermal chemical vapor deposition (CVD) technique, plasma enhanced-CVD (PE-CVD) technique, a physical CVD process, and/or an atomic layer deposition (ALD) technique.

For example, each of the first material layers 111 may include a silicon layer, a silicon oxide layer, a silicon carbide layer, a silicon oxynitride layer, and/or a silicon nitride layer. Each of the second material layers 112 may include a silicon layer, a silicon oxide layer, a silicon carbide layer, a silicon oxynitride layer, and/or a silicon nitride layer. Here, the second material layer 112 includes a material different from the material of the first material layer 111. For example, the first material layers 111 may include silicon nitride layers, and the second material layers 112 may include silicon oxide layers. Alternatively, the first material layers 111 may include a conductive material, and the second material layers 112 may include an insulating material.

A lower insulating layer 105 may be formed between the substrate 100 and the thin layer-structure 110. For example, the lower insulating layer 105 may include a silicon oxide layer by a thermal oxidation process. Alternatively, the lower insulating layer 105 may include a silicon oxide layer formed by a deposition technique. The lower insulating layer 105 may include a thickness less than that of the first and second material layers 111 and 112 formed on the lower insulating layer 105.

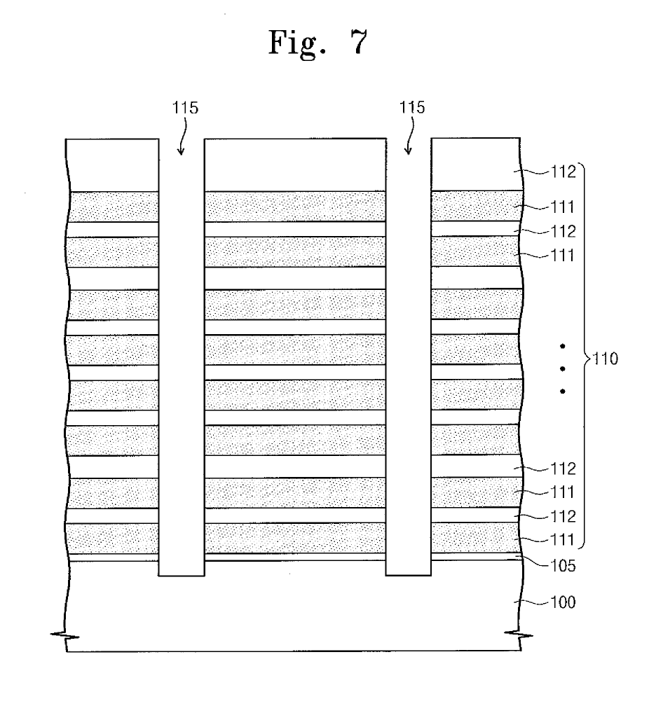

Referring to FIG. 7, openings 115 are formed to penetrate the thin layer-structure 110. The openings 115 expose the substrate 100.

For example, the openings 115 may be formed to have hole-shapes. Each of the openings 115 may have a depth five or more times greater than a width thereof. The openings 115 may be two-dimensionally arranged on a top surface (i.e., a xy plane) of the substrate 100. The openings 115 may be spaced apart from each other in an x-axis direction and a y-axis direction. Alternatively, the openings 115 may be arranged in a zigzag form along the x-axis direction. A distance between openings 115 adjacent to each other in one direction may be equal to or smaller than the width of the opening 115.

The openings 115 may be formed by a patterning process. For example, a mask pattern (not shown) may be formed on the thin layer-structure 110 and then the thin layer-structure 110 may be anisotropically etched using the mask pattern (not shown) as an etch mask to form the openings 115. In the anisotropic etching process, the substrate 110 under the openings 115 may be over-etched. Thus, the substrate 100 under the openings 115 may be recessed by a predetermined depth.

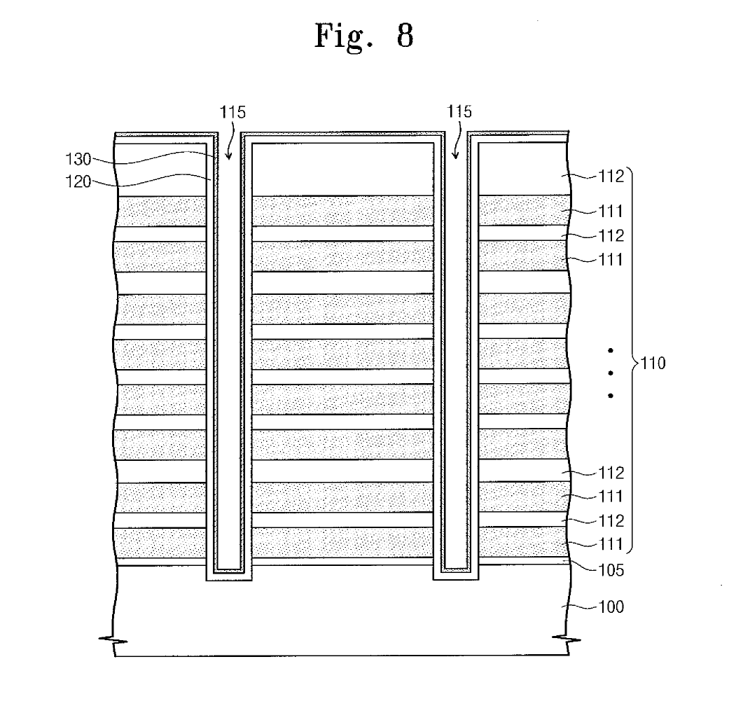

Next, a method of forming a vertical insulator and a channel structure in the opening 115 will be described in detail with reference to FIGS. 8 to 11. Additionally, a method of forming the vertical insulator including a plurality of thin layers and the channel structure including a plurality of thin layers will be described in more detail with reference to FIGS. 15 to 18 and FIGS. 19 to 26.

Referring to FIG. 8, a vertical insulating layer 120 and a first semiconductor layer 130 may be sequentially formed to cover an inner sidewall of the opening 115.

The vertical insulating layer 120 and the first semiconductor layer 130 may be deposited conformally on an inner sidewall of the opening 115. A sum of thicknesses of the vertical insulating layer 120 and the first semiconductor layer 130 may be smaller than a half of the width of the opening 115. Thus, the opening 115 might not be completely filled with the vertical insulating layer 120 and the first semiconductor layer 130. Additionally, the vertical insulating layer 120 may cover the substrate 100 exposed by the opening 115.

The vertical insulating layer 120 may include a plurality of thin layers. For example, the vertical insulating layer 120 may include a high-k dielectric layer, a blocking insulating layer, a charge storing layer, and a tunnel insulating layer which are used as a memory element of a flash memory device. For example, the vertical insulating layer 120 may be formed using a PE-CVD technique, a physical CVD technique, and/or an ALD technique.

The first semiconductor layer 130 may be conformally formed on the vertical insulating layer 120. For example, the first semiconductor layer 130 may include a semiconductor material (e.g., poly-crystalline silicon, single-crystalline silicon, amorphous silicon) formed by an ALD technique and/or a CVD technique.

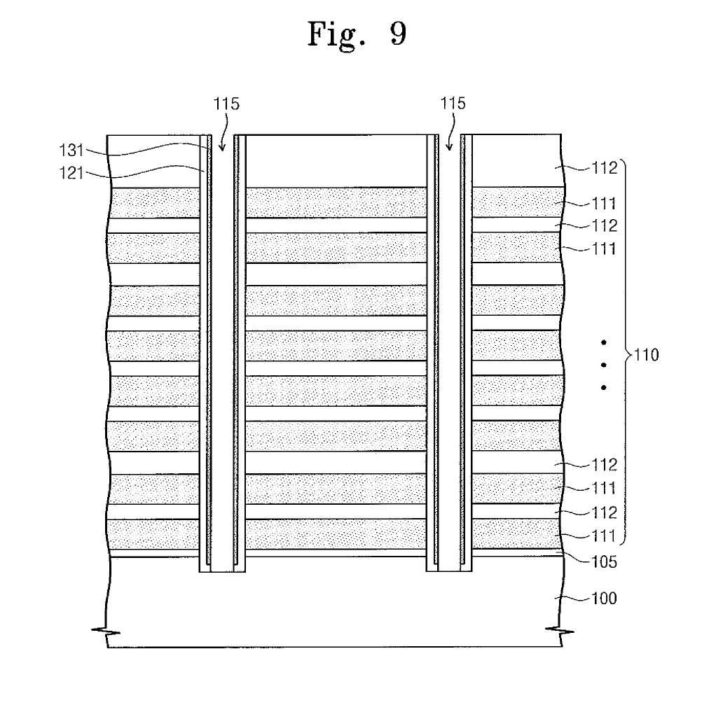

Referring to FIG. 9, the first semiconductor layer 130 and the vertical insulating layer 120 on bottom surfaces of the opening 115 may be anisotropically etched to expose the substrate 100. Thus, a vertical insulator 121 and a first semiconductor pattern 131 may be formed on the inner sidewall of the opening 115. Each of the vertical insulator 121 and the first semiconductor pattern 131 may have a hollow cylinder-shape of which both ends are open. Additionally, the substrate 100 exposed by the first semiconductor pattern 131 may be recessed by over-etching during the anisotropic etching process performed on the first semiconductor layer 130 and the vertical insulating layer 120.

For example, a portion of the vertical insulating layer 120 under the first semiconductor pattern 131 may remain during the anisotropic etching process of the first semiconductor layer 130 and the vertical insulating layer 120. For example, the vertical insulator 121 may have a bottom portion disposed between a bottom surface of the first semiconductor pattern 131 and the substrate 100.

Additionally, a top surface of the thin layer-structure 110 may be exposed by the anisotropic etching process of the first semiconductor layer 130 and the vertical insulating layer 120. Thus, the vertical insulator 121 and the first semiconductor pattern 131 may remain on the inner sidewall of the opening 115. The vertical insulators 121 and the first semiconductor patterns 131 may be two-dimensionally arranged in a plan view.

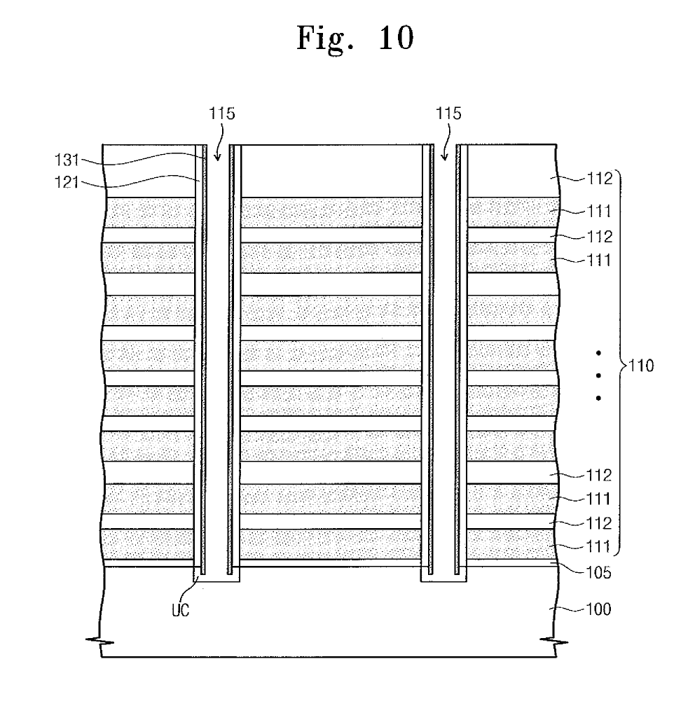

Referring to FIG. 10, a bottom portion of the vertical insulator 121 between the bottom surface of the first semiconductor pattern 131 and the substrate 100 may be removed.

For example, the bottom portion of the vertical insulator 121 may be exposed by the opening 115. The exposed bottom portion of the vertical insulator 121 may be isotropically etched to expose the bottom surface of the first semiconductor pattern 131. Thus, a vertical length of the vertical insulator 121 may be less than a vertical length of the first semiconductor pattern 131. Additionally, an undercut region UC may be formed under the vertical insulator 121 and the first semiconductor pattern 131. The vertical insulator 121 and the first semiconductor pattern 131 may be spaced apart from the substrate 100 in the undercut region UC.

For example, since the vertical insulator 121 includes the plurality of thin layers, isotropically etching the bottom portion of the vertical insulator 121 may include isotropically etching the plurality of thin layers. The isotropic etching process of the bottom portion of the vertical insulator 121 may be performed using an isotropic wet etching method and/or an isotropic dry etching method. The isotropic wet etching method may use an etching solution including hydrofluoric acid or sulfuric acid.

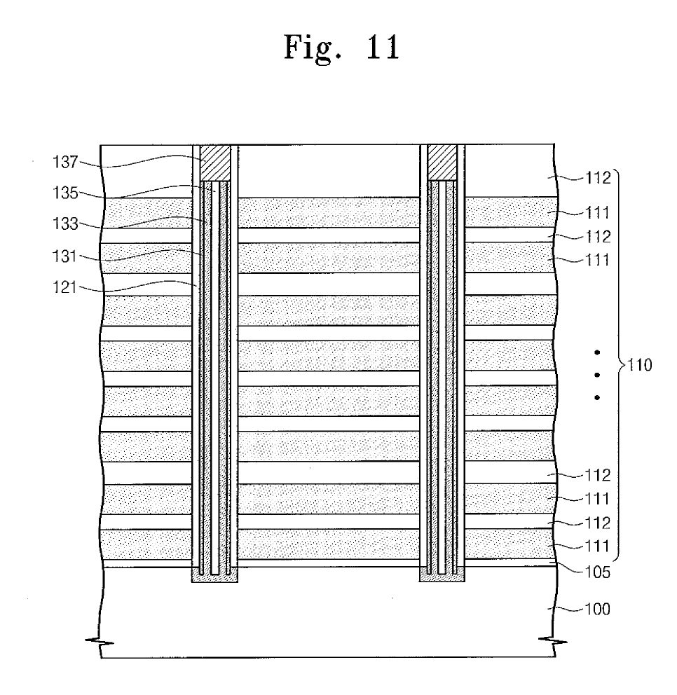

Referring to FIG. 11, a second semiconductor pattern 133 and a filling insulating pattern 135 may be formed on the substrate 100 having the vertical insulator 121 and the first semiconductor pattern 131.

For example, a second semiconductor layer and an filling insulating layer may be sequentially formed in the opening 115 having the vertical insulator 121 and the first semiconductor pattern 131 and on the substrate 100, and then the filling insulating layer and the second semiconductor layer may be planarized until the top surface of the thin layer-structure 110 is exposed Thus, the second semiconductor pattern 133 and the filling insulating pattern 135 may be formed in the opening 115.

The second semiconductor layer (not shown) may be conformally formed in the opening 115 to such a thickness that the second semiconductor layer does not fill the opening 115. The second semiconductor layer may connect the substrate 100 to the first semiconductor pattern 131 and may be conformally formed on an inner sidewall of the first semiconductor pattern 131 and in the undercut region UC. The second semiconductor layer may include a semiconductor layer (e.g., a poly-crystalline silicon layer, a single-crystalline silicon layer, or an amorphous silicon layer) formed by an ALD technique and/or a CVD technique. For example, the second semiconductor layer may be deposited conformally on the inner sidewall of the first semiconductor pattern 131 in the undercut region UC, covering conformally an inner surface of the undercut region UC. Thus, the second semiconductor layer may define a seam in the undercut region UC. Alternatively, the second semiconductor layer may be partially fill the undercut region UC, so that a void may be formed in the undercut region UC and the filling insulating layer may fill the void.

The second semiconductor pattern 133 formed by the method described above may have a hollow pipe-shape, a hollow cylinder-shape, or a cup-shape. Alternatively, the second semiconductor pattern 133 may fully fill the opening 115.

The filling insulating pattern 135 may be formed on the second semiconductor pattern 133 to fill the opening 115. The filling insulating pattern 135 may include silicon oxide and/or insulating materials formed using a spin-on-glass (SOG) technique.

After the second semiconductor pattern 133 and the filling insulating pattern 135 are formed, a conductive pad 137 may be formed to be connected to the first and second semiconductor patterns 131 and 133. Upper portions of the first and second semiconductor patterns 131 and 133 may be recessed and then a conductive material (not shown) may be formed to fill the recessed region, so that the conductive pad 137 may be formed. Additionally, the conductive pad 137 may be doped with dopants of a conductivity type different from those of the first and second semiconductor patterns 131 and 133 under the conductive pad 137. Thus, the conductive pad 137 may constitute a diode in company with the first and second semiconductor patterns 131 and 133.

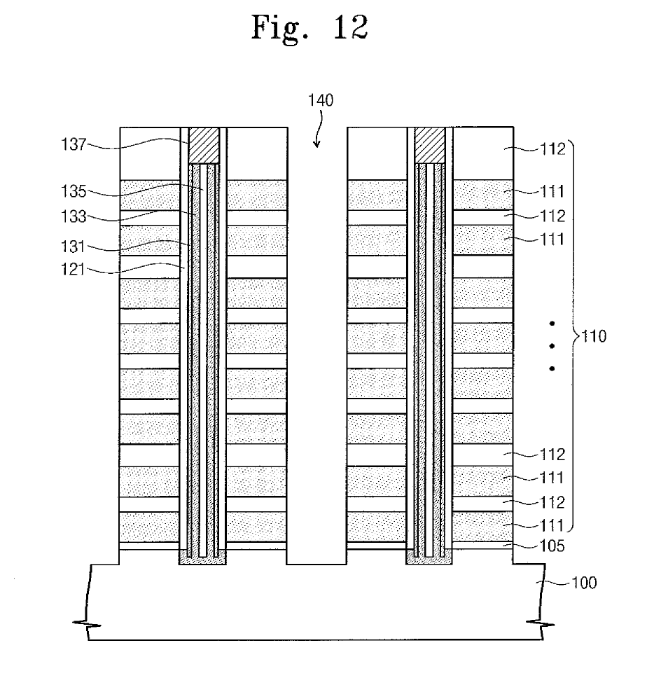

Referring to FIG. 12, the thin layer-structure 110 may be patterned trenches 140 exposing the substrate 100. Each of the trenches 140 may be disposed between the openings 115 adjacent to each other. In a plan view, the trenches 140 may have line-shapes or rectangular shapes extending in a direction perpendicular to the cross-sectional view.

For example, a mask pattern (not shown) defining the trenches 140 may be formed on the thin layer-structure 110 and then the thin layer-structure 110 may be anisotropically etched using the mask pattern (not shown) as an etch mask.

The trenches 140 may expose sidewalls of the patterned first and second material layers 111 and 120. The trenches 140 may expose the substrate 100. The substrate 100 exposed by the trenches 140 may be recessed by a predetermined depth due to over-etching in the formation of the trenches 140. A width of the trench 140 may become progressively varied from the substrate 100 toward a top end of the trench 140.

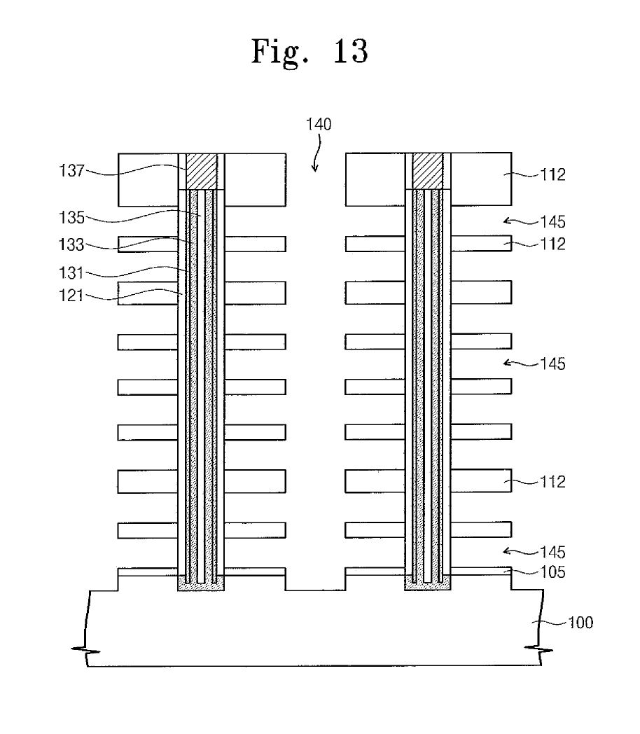

Referring to FIG. 13, recess regions 145 are formed by removing the first material layers 111 between the second material layers 112.

For example, each of the recess regions 145 may be defined by the two adjacent second material layers 112 and the portion of the sidewall of the vertical insulator 121.

For example, the first material layers 111 may be isotropically etched using an etchant having etch selectivity with respect to the second material layers 112 and the substrate 100. The first material layers 111 may be completely removed by the isotropic etching process. For example, if the first material layers 111 are silicon nitride layers and the second material layers 112 are silicon oxide layers, the etchant may include phosphoric acid.

Referring to FIG. 14, gate patterns 150 may be formed to fill the recess regions 145, respectively.

A conductive layer (not shown) may be formed to fill the recess regions 145 and the trenches 140. The conductive layer formed in the trenches 140 may be removed, and the conductive layer that remains in the recess regions 145 may become gate patterns 150.

For example, the conductive layer may be deposited conformally on the recess regions 145. The conductive layer in the trenches 140 may be anisotropically etched to form the gate patterns 150. The conductive layer may include doped silicon, metal materials, metal nitrides, and/or metal silicides. For example, the conductive layer may include a metal material such as tantalum nitride and/or tungsten.

The gate pattern 150 may in contact with the portion of the vertical insulator 121 exposed by the recess regions 145. Additionally, the gate pattern 150 may be in contact with a bottom surface of the second insulating layer 112 directly on the gate pattern 150 and a top surface of the second insulating layer 112 directly under the gate pattern 150.

Dopant regions 107 may be formed in the substrate 100. For example, the dopant regions 107 may be formed by an ion implantation process and may be formed in the substrate 100 exposed through the trenches 140. The dopant regions 107 may have a conductivity type different from those of the first and second semiconductor patterns 131 and 133. The dopant region 107 and the substrate 100 may constitute a PN junction at their boundary. The substrate 100 being in contact with the second semiconductor pattern 133 may have a same conductivity type as that of the second semiconductor pattern 133. The dopant regions 107 may be connected to each other to be in an equipotential state. Alternatively, the dopant regions 107 may be electrically separated from each other in order that each of the dopant regions 107 is controlled independently from the others of the dopant regions 107. Alternatively, the dopant regions 107 may be divided into a plurality of source groups controlled independently from each other. Each of the source groups may include a plurality of the dopant regions 107. The source groups may be electrically separated from each other in order that they are controlled independently from each other.

The electrode separating patterns 160 may be formed to fill the trenches 140, respectively. The electrode separating patterns 160 may include silicon oxide, silicon nitride, and/or silicon oxynitride.

As shown in FIG. 2, contact plugs 171 and a bit line 175 may be formed on the structure of FIG. 14. The contact plugs 171 may be connected to the conductive pads 137, and the bit line 175 may be connected to the contact plugs 171. The bit line 175 may cross over the structure of FIG. 14. The bit line 175 may be electrically connected to the first and second semiconductor patterns 131 and 133 through the contact plug 171.

A method of forming a vertical insulator of a 3D semiconductor memory device according to an exemplary embodiment will be described in detail with reference to FIGS. 15 to 18. FIGS. 15 to 18 are partial cross-sectional views illustrating a method of fabricating a 3D semiconductor memory device according to an exemplary embodiment of the inventive concept. FIGS. 15 to 18 are cross-sectional views for illustrating manufacturing steps of manufacturing portion ‘A” of FIG. 2.

Referring to FIG. 15, after the opening 115 is formed to penetrate the thin layer-structure 110 as illustrated in FIG. 7, a capping layer CPL, a high-k dielectric layer HDL, an blocking insulating layer BIL, a charge storing layer CTL, and a tunnel insulating layer TIL may be sequentially deposited in the opening 115. Subsequently, as described with reference to FIGS. 8 to 11, the first semiconductor pattern 131, the second semiconductor pattern 133, and the filling insulating pattern 135 may be formed in the opening 115 having the capping layer CPL, the high-k dielectric layer HDL, the blocking insulating layer BIL, the charge storing layer CTL, and the tunnel insulating layer TIL.

The capping layer CPL, the high-k dielectric layer HDL, the blocking insulating layer BIL, the charge storing layer CTL, and the tunnel insulating layer TIL may be deposited using a PE-CVD technique, a physical CVD technique, and/or an ALD technique.

The capping layer CPL may be formed to be in contact with sidewalls of the first and second material layers 111 and 112 which are exposed by the opening 115. The capping layer CPL may include a material having etch selectivity with respect to the high-k dielectric layer HDL. Additionally, the capping layer CPL may include a material having etch selectivity with respect to the first and second material layers 111 and 112. Alternatively, the capping layer CPL may have etch selectivity with respect to the second material layers 112 and have a same material as that of the first material layers 111. For example, the capping layer CPL may include a silicon layer, a silicon oxide layer, a poly-silicon layer, a silicon carbide layer, and/or a silicon nitride layer.

The charge storing layer CTL may include a trap insulating layer, or an insulating layer including conductive nano dots. For example, the charge storing layer CTL may include a silicon nitride layer, a silicon oxynitride layer, a silicon-rich nitride layer, a nano-crystalline silicon layer, and/or a laminated trap layer.

The tunnel insulating layer TIL may include an insulating material having an energy band gap greater than that of the charge storing layer CTL. For example, the tunnel insulating layer TIL may include a silicon oxide layer.

The blocking insulating layer BIL may include an insulating material having an energy band gap greater than that of the charge storing layer CTL. For example, the blocking insulating layer BIL may include a silicon oxide layer.

The high-k dielectric layer HDL may include a material having a dielectric constant greater than that of the blocking insulating layer BIL. For example, a metal oxide having a high-k dielectric constant may be deposited on the inner sidewall of the opening 115 to form the high-k dielectric layer HDL. For example, the high-k dielectric layer HDL may include tantalum oxide (Ta₂O₅), titanium oxide (TiO₂), hafnium oxide (HfO₂), zirconium oxide (ZrO₂), hafnium silicate (HfSixOy), zirconium silicate (ZrSixOy), hafnium silicate nitride (HfSixOyNz), zirconium silicate nitride (ZrSixOyNz), aluminum oxide (Al₂O₃), aluminum oxynitride (AlxOyNz), hafnium aluminate (HfAlxOy), yttrium oxide (Y₂O₃), niobium oxide (Nb₂O₅), cerium oxide (CeO₂), indium oxide (InO₃), lanthanum oxide (LaO₂), ((Ba,Sr)TiO₃, BST), (Pb(Zr,Ti)O₃, PZT), strontium-titanium oxide (SrTiO₃), lead-titanium oxide (PbTiO₃), strontium-ruthenium oxide (SrRuO₃), calcium-ruthenium oxide (CaRuO₃), (Pb,La)(Zr,Ti)O₃, and/or (Sr,Ca)RuO₃. The high-k dielectric layer HDL may be single-layered. Alternatively, the high-k dielectric layer HDL may have a laminated structure including stacked thin layers.

According to an exemplary embodiment, the vertical insulator 121 illustrated in FIG. 15 may include the capping layer CPL, the high-k dielectric layer HDL, the blocking insulating layer BIL, the charge storing layer CTL, and the tunnel insulating layer TIL which are sequentially stacked on the inner sidewall of the opening 115. For example, the vertical insulator 121 may include silicon oxide/high-k dielectric (HDL)/silicon oxide/silicon nitride/silicon oxide.

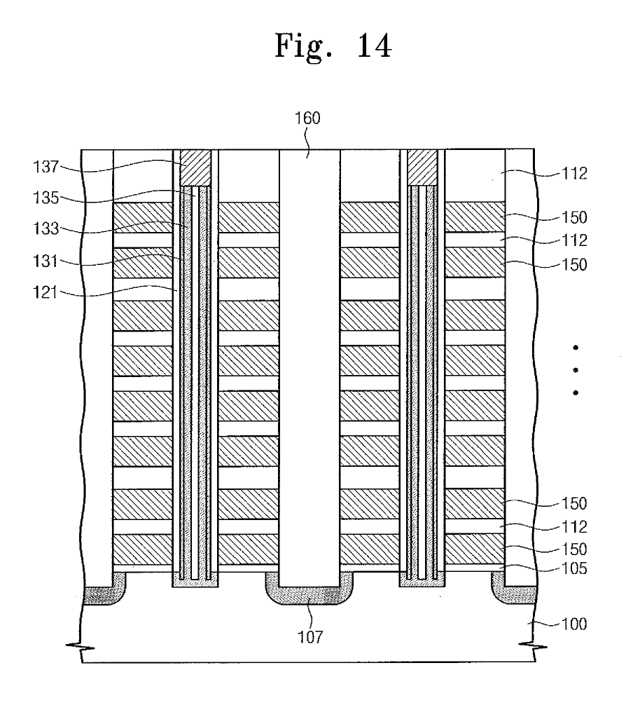

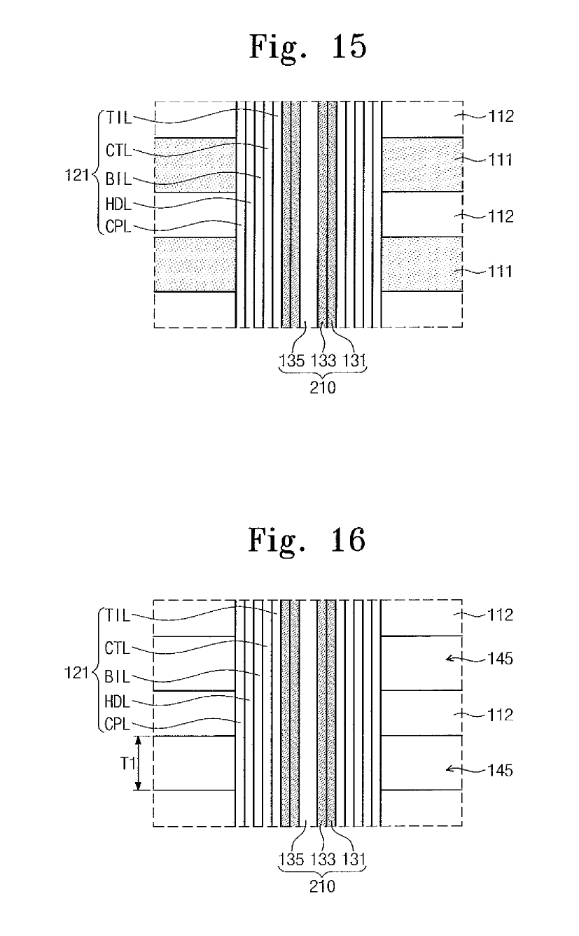

Referring to FIG. 16, the recess regions 145 may be formed by removing the first material layers 111 of FIG. 12 using an etchant having etch selectivity with respect to the capping layer CPL. The recess regions 145 may expose portions of the vertical insulator 121. Here, a vertical height T1 of the recess region 145 may be substantially equal to a thickness of the first material layer 111 (i.e., a vertical distance between the second material layers 112 vertically adjacent to each other). The capping layer CPL may be used as an etch stop layer during the isotropic etching process performed on the first material layers 111. The capping layer CPL may prevent the high-k dielectric layer HDL from being damaged by the etchant. For example, the recess region 145 may expose the capping layer CPL of the vertical insulator 121.

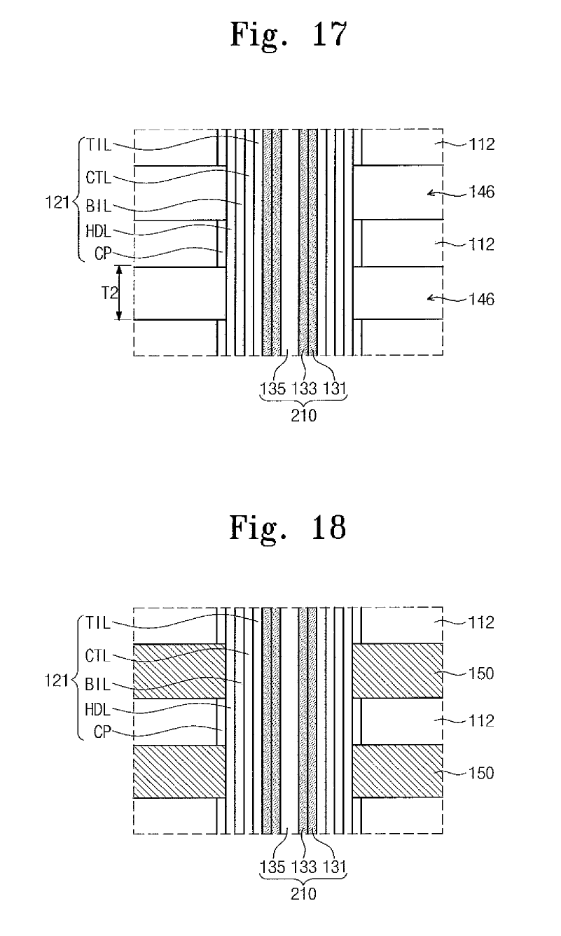

Referring to FIG. 17, the exposed capping layer CPL and portions of the second material layers 112 may be isotropically etched to form enlarged recess regions 146. For example, when the enlarged recess regions 146 are formed, portions of the capping layer CPL may be etched to expose portions of the high-k dielectric layer HDL. Here, if the capping layer CPL and the second material layers 112 are formed of the same material, the vertical thicknesses of the second material layers 112 may be reduced to form the enlarged recess regions 146. In other words, a vertical height T2 of the enlarged recess region 146 may be greater than the vertical height T1 of the recess region 145 illustrated in FIG. 16. Here, a difference (T2-T1) between the vertical heights T2 and T1 of the enlarged recess region 146 and the recess region 145 may be about two times greater than a thickness of the capping layer CPL.

Capping patterns CP may remain between the high-k dielectric layer HDL and the second material layers 112 by the formation of the enlarged recess regions 146.

Referring to FIG. 18, the gate patterns 150 may be formed in the enlarged recess regions 146, respectively. The gate pattern 150 may be in contact with the high-k dielectric layer HDL, the second material layer 112 directly on the gate pattern 150, and the second material layer 112 directly under the gate pattern 150. Additionally, the gate pattern 150 may be disposed between the capping patterns CP vertically separated from each other.

Hereinafter, a method of forming a vertical insulator of a 3D semiconductor memory device according to an exemplary embodiment will be described with reference to FIGS. 19 to 26. FIGS. 19 to 26 are partial cross-sectional views illustrating a method of fabricating a 3D semiconductor memory device according to an exemplary embodiment of the inventive concept. FIGS. 19 to 26 illustrate the portion ‘A’ of FIG. 4.

Referring to FIG. 19, after the openings 115 penetrating the thin layer-structure 110 are formed as illustrated in FIG. 7, a semiconductor pillar 220 may be formed to fill a lower region of each of the openings 115.

A selective epitaxial growth (SEG) process may be performed using the substrate 100 exposed by the opening 115 as a seed layer to form the semiconductor pillar 220. Thus, the semiconductor pillar 220 may be formed in a single-crystalline structure. The semiconductor pillar 220 may have a same conductivity type as that of the substrate 100. The semiconductor pillar 220 may be doped with dopants in situ during the SEG process. Alternatively, after the semiconductor pillar 220 is formed, the semiconductor pillar 220 may be doped by an ion implantation process. The semiconductor pillar 220 may be in contact with the first and second material layers 111 and 112 of a lower portion of the thin layer-structure.

Referring to FIG. 20, the high-k dielectric layer HDL may be conformally formed on the inner sidewall of the opening 115. For example, the high-k dielectric layer HDL may conformally cover an inner sidewall of the first and second material layers 111 and 112 exposed by the opening 115 and a top surface of the semiconductor pillar 220.

The high-k dielectric layer HDL may include a high-k dielectric material including hafnium (Hf). For example, the high-k dielectric layer HDL may include hafnium oxide (HfO₂), hafnium silicate (HfSixOy), hafnium silicate nitride (HfSixOyNz), and/or hafnium aluminate (HfAlxOy).

The high-k dielectric layer HDL may be deposited using an ALD technique. For example, the ADL technique may include an ALD cycle which includes supplying a hafnium source material, supplying a purge gas, supplying an oxidant, and supplying a purge gas. The ALD cycle may be repeatedly performed to form the high-k dielectric layer HDL. After the high-k dielectric layer HDL having a predetermined thickness is formed, an annealing process may be performed for improving properties of the high-k dielectric layer HDL.

For example, the hafnium source material such as tetrakis diethylamino hafnium (TDEAH) and/or Hf(OtBu)₄ may be supplied into the opening 115. Thus, a portion of the hafnium source material may be chemically adsorbed on the inner sidewall of the opening 115 and the top surface of the thin layer-structure 110, and the rest portion of the hafnium source material may be physically adsorbed thereon. Subsequently, the purge gas such as an argon gas may be supplied into the opening 115 to remove the rest portion of the hafnium source material physically adsorbed on the inner sidewall of the opening 115 and the top surface of the thin layer-structure 110. Next, the oxidant such as O₃ may be supplied into the opening 115. Thus, the chemically adsorbed portion of the hafnium source material may react with the oxidant to form the high-k dielectric layer HDL including hafnium oxide on the inner sidewall of the opening 115. Thereafter, the purge gas may be supplied to remove the oxidant not reacting with the chemically adsorbed portion of the hafnium source material. Alternatively, the high-k dielectric layer HDL may be deposited by a plasma enhanced CVD or a physical CVD.

Additionally, when the high-k dielectric layer HDL including hafnium is deposited, an insufficiently oxidized hafnium-silicon oxide layer IL may be formed at an interface between the high-k dielectric layer HDL and the semiconductor pillar 220 (or the substrate 100).

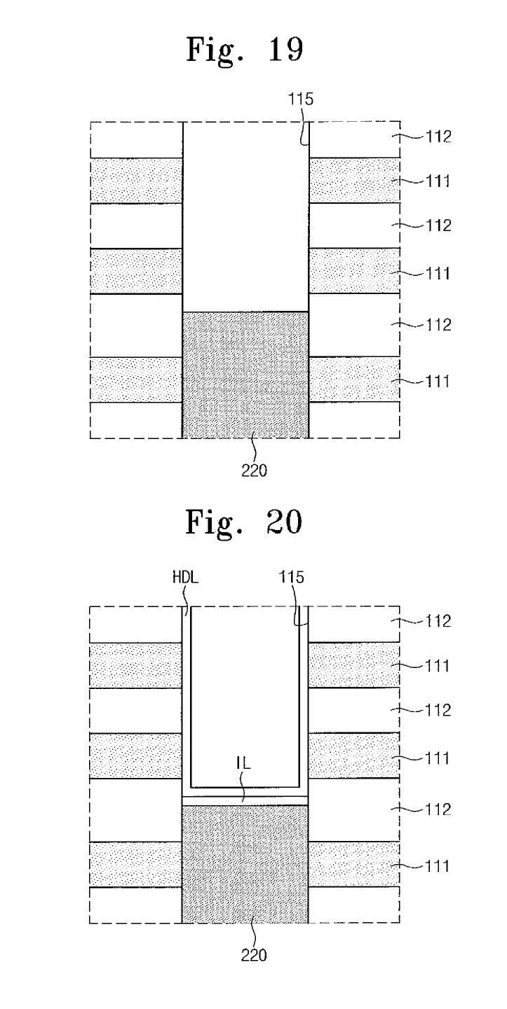

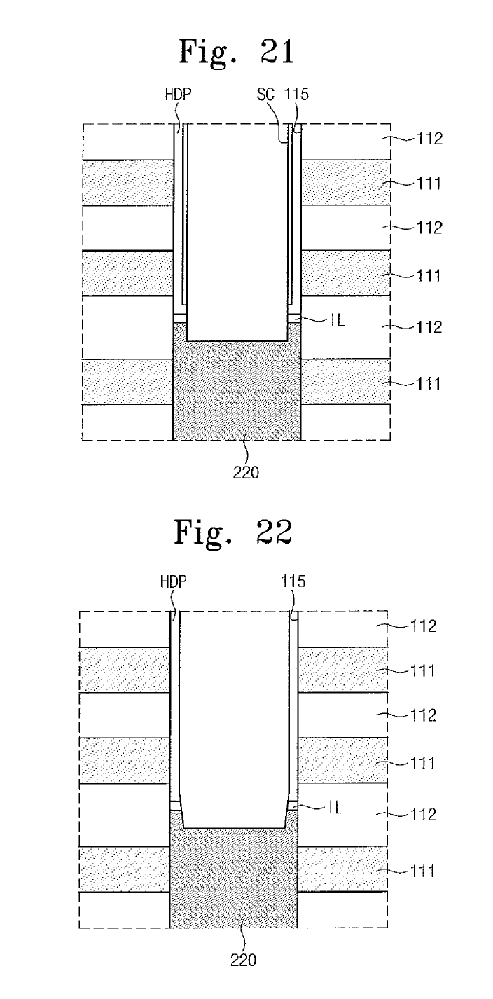

Referring to FIG. 21, the high-k dielectric layer HDL on the top surface of the semiconductor pillar 220 may be etched to form a high-k dielectric pattern HDP on the inner sidewall of the opening 115.

Forming the high-k dielectric pattern HDP may include depositing a sacrificial layer conformally on the high-k dielectric layer HDL. The sacrificial layer may be etched anisotropically to form a sacrificial spacer SC exposing the high-k dielectric layer HDL on the top surface of the semiconductor pillar 220. And then, the high-k dielectric layer HDL exposed by the sacrificial spacer SC may be etched isotropically. Here, the high-k dielectric layer may be chemically very stable and be an inert material which does not form easily volatile active species. Thus, the high-k dielectric layer HDL may be formed to be very thin for a dry etching. The high-k dielectric layer HDL on the top surface of the semiconductor pillar 220 (or the substrate 100) may be etched anisotropically.

Additionally, a depositing thickness of the sacrificial layer may be very thin for increasing an area of the exposed top surface of the semiconductor pillar 220 through the opening 115. For example, the sacrificial layer may include a silicon nitride layer, and the thickness of the sacrificial layer may be within a range of about 10 Å to about 100 Å.

As described above, the high-k dielectric layer HDL may be anisotropically etched to form the high-k dielectric pattern HDP of a hollow cylinder-shape. Additionally, the hafnium-silicon oxide layer IL exposed by the high-k dielectric pattern HDP may be etched when the high-k dielectric layer HDL is anisotropically etched. Furthermore, the top surface of the semiconductor pillar 220 (or the substrate 100) may be recessed.

Referring to FIG. 22, the sacrificial spacer SC may be removed to expose an inner sidewall of the high-k dielectric pattern HDP. The sacrificial spacer SC may be removed using an isotropic etching process. The isotropic etching process may be performed using an isotropic wet etching process or an isotropic dry etching process. If the sacrificial spacer SC is formed of silicon nitride, the isotropic etching process for removing the sacrificial spacer SC may be performed using an etching solution including phosphoric acid.

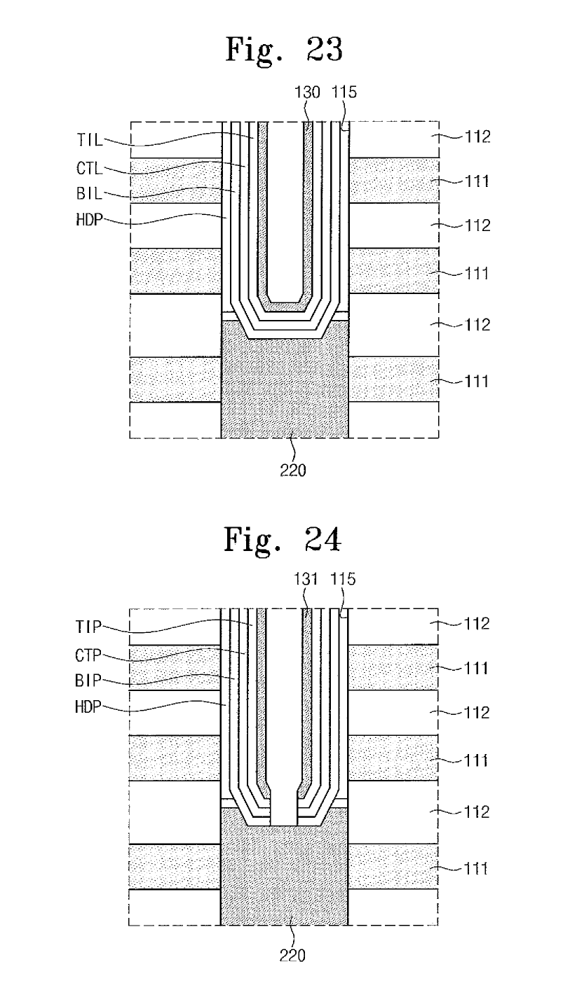

Referring to FIG. 23, the blocking insulating layer BIL, the charge storing layer CTL, the tunnel insulating layer TIL, and the first semiconductor layer 130 may be sequentially formed in the opening 115 having the high-k dielectric pattern HDP.

A sum of thicknesses of the blocking insulating layer BIL, the charge storing layer CTL, the tunnel insulating layer TIL, and the first semiconductor layer 130 may be less than a half of the width of the opening 115. In other words, the opening 115 may remain unfilled with the blocking insulating layer BIL, the charge storing layer CTL, the tunnel insulating layer TIL, and the first semiconductor layer 130. Additionally, the blocking insulating layer BIL, the charge storing layer CTL, the tunnel insulating layer TIL, and the first semiconductor layer 130 may cover the exposed top surface of the semiconductor pillar 220.

Referring to FIG. 24, the blocking insulating layer BIL, the charge storing layer CTL, the tunnel insulating layer TIL, and the first semiconductor layer 130 on the top surface of the semiconductor pillar 220 may be anisotropically etched to expose the top surface of the semiconductor pillar 220. Thus, a blocking insulating pattern BIP, a charge storing pattern CTP, a tunnel insulating pattern TIP, and a first semiconductor pattern 131 may be formed in the opening 115.

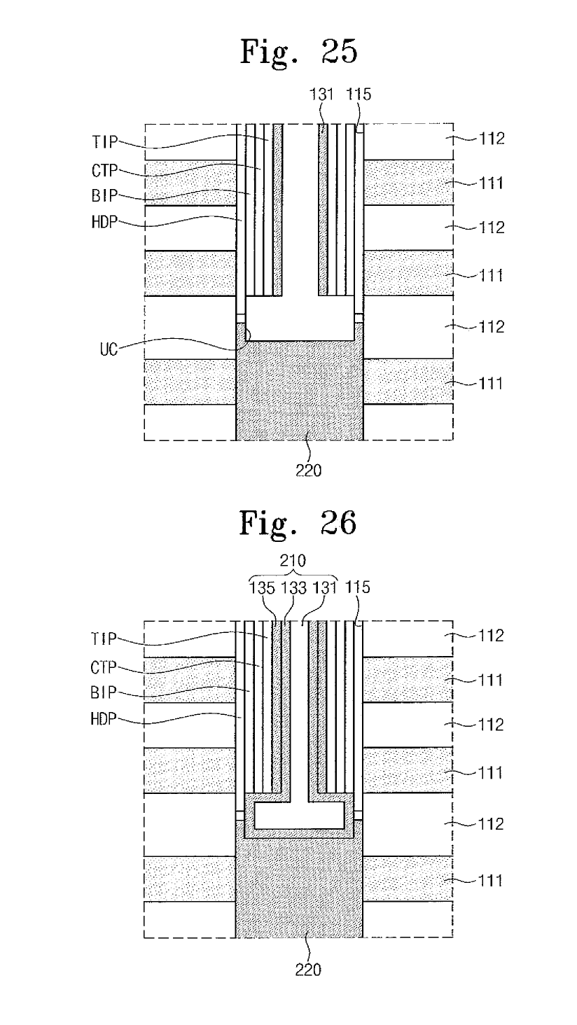

Referring to FIG. 25, portions of the blocking insulating pattern BIP, the charge storing pattern CTP, and the tunnel insulating pattern TIP between the first semiconductor pattern 131 and the top surface of the semiconductor pillar 220 may be isotropically etched to form the undercut region UC. Vertical lengths of the blocking insulating pattern BIP, the charge storing pattern CTP, and the tunnel insulating pattern TIP may be reduced by the formation of the undercut region UC. The blocking insulating pattern BIP, the charge storing pattern CTP, and the tunnel insulating pattern TIP may be separated from the top surface of the semiconductor pillar 220. Additionally, a lower sidewall of the high-k dielectric pattern HDP may be exposed by the undercut region UC. For example, the vertical lengths of the blocking insulating pattern BIP, the charge storing pattern CTP, and the tunnel insulating pattern TIP may be smaller than a vertical length of the high-k dielectric pattern HDP.

According to an exemplary embodiment, the tunnel insulating pattern TIP and the blocking insulating pattern BIP may include a silicon oxide layer. The charge storing pattern CTP may include a silicon nitride layer. In this case, an isotropic etching process for forming the undercut region UC includes an isotropic etching step for the tunnel insulating pattern TIP and the blocking insulating pattern BIP and an isotropic etching step for the charge storing pattern CTP. The charge storing pattern CTP may be formed through a wet etch process using, for example, an etchant with phosphoric acid.

The tunnel insulating pattern TIP and the blocking insulating pattern BIP may be formed through a wet etch process using, for example, an etchant including hydrofluoric acid and/or sulfuric acid. When the isotropic etching for forming the undercut region UC is processed, the first semiconductor layer pattern 131 and the high-k dielectric pattern HDP (e.g., a dielectric material comprising hafnium (Hf)) may have etch selectivity with respect to the TIP, CTP, and BIP. Therefore, the first semiconductor layer pattern 131 and the high-k dielectric pattern HDP remains after the isotropic etching process for forming the undercut region UC.

Referring to FIG. 26, a second semiconductor pattern 133 may be formed in the opening 115 having the undercut region UC. The second semiconductor pattern 133 may connect the first semiconductor pattern 131 to the semiconductor pillar 220. The second semiconductor pattern 133 may conformally cover an inner surface of the undercut region UC by a depositing process. For example, the second semiconductor pattern 133 may be in contact with bottom surfaces of the blocking insulating pattern BIP, the charge storing pattern CTP, the tunnel insulating pattern TIP, and the first semiconductor pattern 131. Additionally, the second semiconductor pattern 133 may be in contact with the lower sidewall of the high-k dielectric pattern HDP.

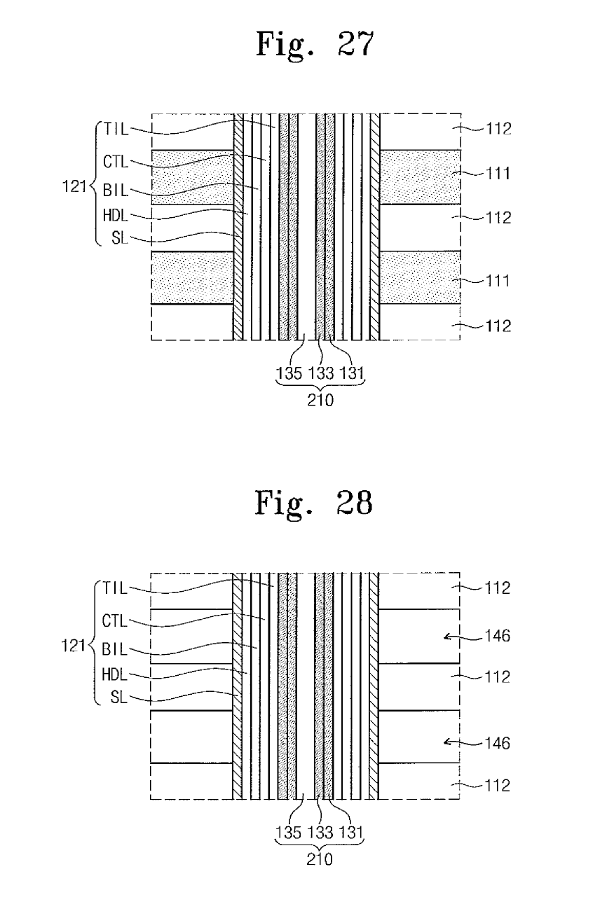

A method of forming a vertical insulator of a 3D semiconductor memory device according to an exemplary embodiment will be described with reference to FIGS. 27 to 33. FIGS. 27 to 33 are partial cross-sectional views illustrating a method of fabricating a 3D semiconductor memory device according to an exemplary embodiment of the inventive concept.

Referring FIG. 27, a poly-silicon layer SL may be formed to be in contact with the inner sidewall of the opening 115 (i.e., an inner sidewall of the thin layer-structure 110 exposed by the opening 115). The high-k dielectric layer HDL, the blocking insulating layer BIL, the charge storing layer CTL, and the tunnel insulating layer TIL may be sequentially stacked on the poly-silicon layer SL. For example, the poly-silicon layer SL, the high-k dielectric layer HDL, the blocking insulating layer BIL, the charge storing layer CTL, and the tunnel insulating layer TIL may constitute a vertical insulator 121.

Subsequently, the first semiconductor pattern 131, the second semiconductor pattern 133, and the filling insulating pattern 135 may be formed in the opening 115 having the vertical insulator 121 as described with reference to FIGS. 8 to 11.

Referring to FIG. 28, as described with reference to FIG. 12, the trench 140 of FIG. 12 spaced apart from the first and second semiconductor patterns 131 and 133 may be formed to expose the first and second material layers 111 and 112. Thereafter, the first material layers 111 exposed by the trench 140 of FIG. 12 may be isotropically etched to form recess regions 145 respectively exposing portions of the vertical insulator 121. Here, a vertical height of the recess region 145 may be substantially equal to the thickness of the first material layer 111 (i.e., a vertical distance between the second material layers 112 vertically adjacent to each other). The poly-silicon layer SL may be used as an etch stop layer during the isotropic etching process of the first material layers 111. The poly-silicon layer SL may prevent the high-k dielectric layer HDL from being damaged by the etching solution used in the isotropic etching process of the first material layers 111. The recess region 145 may expose the poly-silicon layer SL of the vertical insulator 121.

Referring to FIG. 28, the poly-silicon layer SL exposed by the recess regions 145 may be removed to expose portions of the high-k dielectric layer HDL. Here, the poly-silicon layer SL may be partially removed by an isotropic dry etching process. For example, the poly-silicon layer SL may be removed by a gas-phase etching (GPE) process.

When the poly-silicon layer SL is partially etched by the isotropic dry etching process, a poly-silicon pattern SP may remain between the high-k dielectric layer HDL and each of the second material layers 112. A vertical thickness of the poly-silicon pattern SP may be less than a vertical thickness of the second material layer 112. Thus, portions of sidewalls of the second material layers 112, which are adjacent to the recess regions 145, may be exposed.

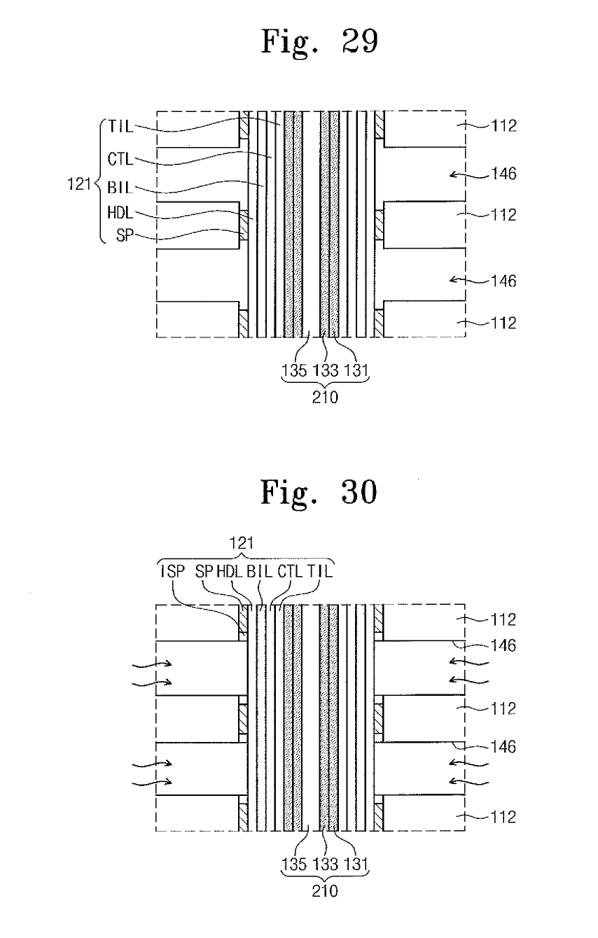

Referring to FIG. 30, a re-oxidation process may be performed on the poly-silicon patterns SP that remains between the high-k dielectric layer HDL and the second material layers 112. The re-oxidation process may include a rapid thermal oxidation process or an oxygen (O₂) plasma treating process. For example, the rapid thermal oxidation process may use oxygen as a reaction gas.

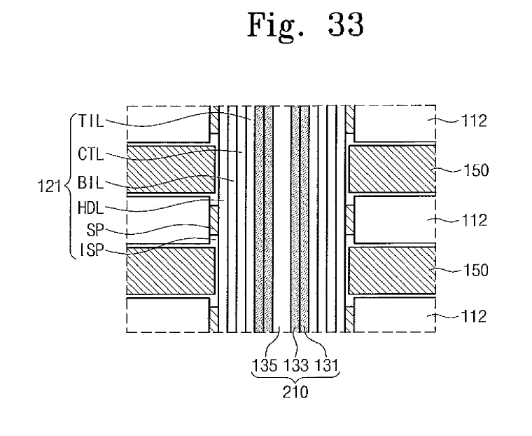

As illustrated in FIG. 30, a silicon oxide pattern ISP adjacent to the recess region 145 may be locally formed between the high-k dielectric layer HDL and the second material layer 112 by the re-oxidation process. Alternatively, as illustrated in FIG. 32, the poly-silicon pattern SP may be completely oxidized by the re-oxidation process. Thus, a silicon oxide layer ISP may be formed between the high-k dielectric layer HDL and the second material layer 112. Alternatively, as illustrated in FIG. 33, top and bottom surfaces of the second material layers 112 and the high-k dielectric layer HDL, which are exposed by the recess regions 145, may be oxidized along with the poly-silicon patterns SP during the re-oxidation process. Thus, a silicon oxide layer ISP may be conformally formed on the inner surface of the recess region 145 which include a surface of the poly-silicon pattern SP, the second material layers 112, and the high-k dielectric layer HDL.

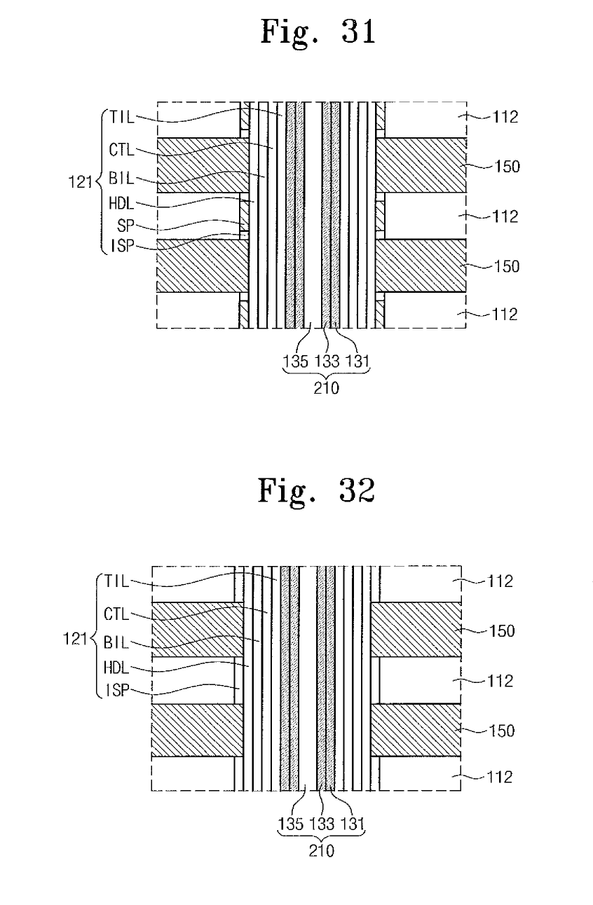

Subsequently, referring to FIG. 31, the gate patterns 150 may be formed in the recess regions 145, respectively. The gate pattern 150 may be in contact with the high-k dielectric layer HDL and the second material layers 112 vertically adjacent to the gate pattern 150 as illustrated in FIG. 31. The gate pattern 150 may be disposed between the silicon oxide patterns ISP vertically adjacent to each other.

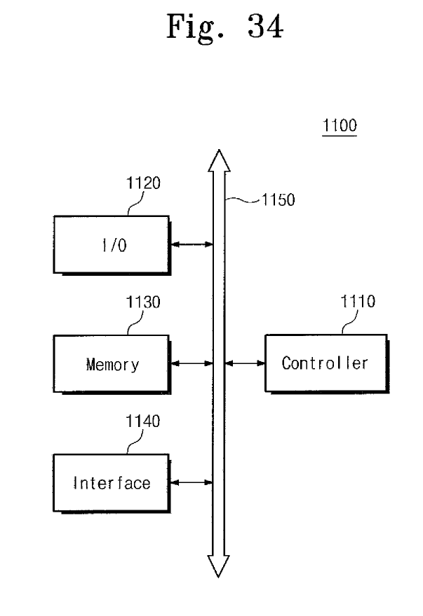

FIG. 34 is a schematic block diagram illustrating an exemplary memory system including a 3D semiconductor memory device according to an exemplary embodiment of the inventive concept.

Referring to FIG. 34, a memory system 1100 may be applied to a personal digital assistant (PDA), a portable computer, a web tablet, a wireless phone, a mobile phone, a digital music player, a memory card, or other electronic products. The other electronic products may receive or transmit information data by wireless.

The memory system 1100 may include a controller 1110, an input/output (I/O) unit 1120, a memory device 1130, an interface unit 1140, and a data bus 1150. At least two of the controller 1110, the I/O unit 1120, the memory device 1130 and the interface unit 1140 may communicate with each other through the data bus 1150.

The controller 1110 may include a microprocessor, a digital signal processor, a microcontroller and/or other logic devices. The other logic devices may have a similar function to any one of the microprocessor, the digital signal processor and the microcontroller. The I/O unit 1120 may receive data or signal from the outside of the system 110 or transmit data or signal to the outside of the system 1100. For example, the I/O unit 1120 may include a keypad, a keyboard and/or a display unit.

The memory device 1130 includes a 3D semiconductor memory device according to an exemplary embodiment. The memory device 1130 may further include other kinds of memory devices including volatile memory devices or non-volatile memory devices.

The interface unit 1140 may transmit data to a communication network or receive data from the communication network.

The 3D semiconductor memory devices and the memory system according to an exemplary embodiment of the inventive concept may be encapsulated using various packaging techniques. For example, the 3D semiconductor memory devices according to an exemplary embodiment may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (S SOP) technique, a thin small outline package (TSOP) technique, a thin quad flat package (TQFP) technique, a system in package (SIP) technique, a multi chip package (MCP) technique, a wafer-level fabricated package (WFP) technique and a wafer-level processed stack package (WSP) technique.

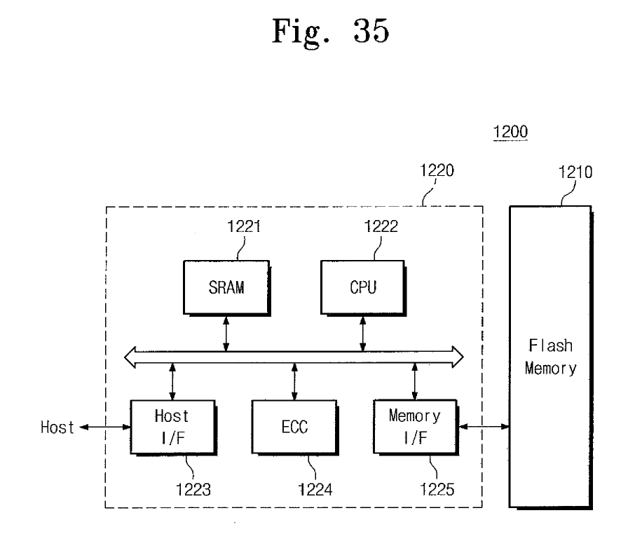

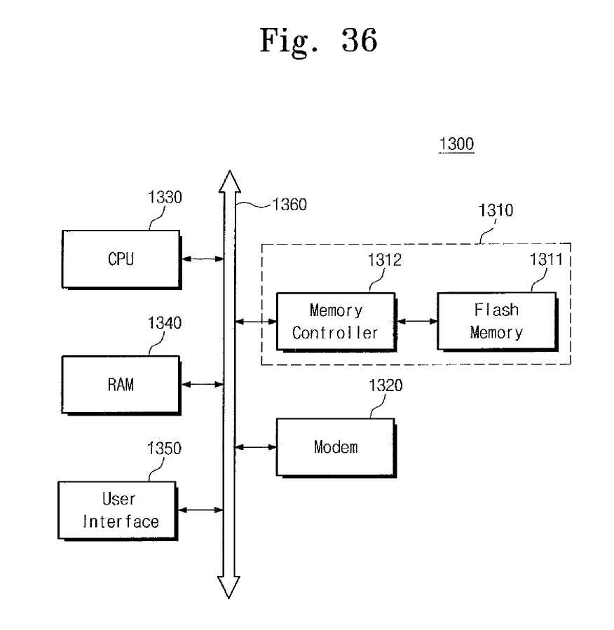

FIG. 35 is a schematic block diagram illustrating an exemplary memory card including a 3D semiconductor memory device according to an exemplary embodiment of the inventive concept.

Referring to FIG. 35, a memory card 1200 for storing massive data may include a flash memory device 1210. The flash memory device 1210 includes a 3D semiconductor memory device according to an exemplary embodiment of the inventive concept. The memory card 1200 according to the inventive concept may include a memory controller 1220 that controls data communication between a host and the flash memory device 1210.

An SRAM device 1221 may be used as an operation memory of a central processing unit (CPU) 1222. A host interface unit 1223 may be configured to include a data communication protocol of a host connected to the memory card 1200. An error check and correction (ECC) block 1224 may detect and correct errors of data which are read out from the memory device 1210. A memory interface unit 1225 may interface with the flash memory device 1210 according to the inventive concept. The CPU 1222 may perform overall operations for data exchange of the memory controller 1220. Even though not shown in the drawings, the memory card 1200 may further include a read only memory (ROM) device that stores code data to interface with the host.

FIG. 36 is a schematic block diagram illustrating an exemplary of an information processing system including a 3D semiconductor memory device according to an exemplary embodiment of the inventive concept.

Referring to FIG. 36, an information processing system 1300 such as a mobile device or a desk top computer may include a flash memory system 1310. The flash memory system 1310 may include a memory controller 1312 and a flash memory device 1311. The flash memory device 1311 includes a 3D semiconductor memory device according to an exemplary embodiment of the inventive concept. The information processing system 1300 according to the inventive concept may include a MODEM 1320, a central processing unit (CPU) 1330, a RAM 1340, a user interface unit 1350 that are electrically connected the flash memory system 1310 through a system bus 1360. The flash memory system 1310 may be substantially the same as the aforementioned memory system or flash memory system. Data processed by the CPU 1330 or data inputted from an external system may be stored in the flash memory system 1310. The flash memory system 1310 may be realized as a solid state disk (SSD). In this case, the information processing system 1300 may stably store massive data in the flash memory system 1310. Reliability of the flash memory system 1310 increases, so that the flash memory system 1310 may decrease a resource for correcting errors to provide a high speed data exchange function to the information processing system 1300. Even though not shown in the drawings, the information processing system 1300 according to the inventive concept may further include an application chipset, a camera image processor (CIS), and/or an input/output unit.

According to an exemplary embodiment of the inventive concept, the vertical insulator may penetrate the stack structure including the gate patterns and the insulating patterns alternately and repeated stacked on the substrate. The vertical insulator may include the tunnel insulating layer, the charge storing layer, the blocking insulating layer, and the high-k dielectric layer. For example, the memory elements disposed between the gate pattern and the channel structure may vertically cross sidewalls of the gate patterns.

Thus, according to at least one embodiment, the vertical height of the stack structure is prevented from increasing by an extension of the memory elements which may extend between the gate pattern and the insulating pattern. In other words, the vertical height of the stack structure is reduced to increase the integration density of the 3D semiconductor memory device.

For convenience of explanation, the above-mentioned terms “layer” and “pattern” have been used interchangeably to indicate a same element according to a manufacturing step. For example, a high-k dielectric layer can be used as a high-k dielectric pattern in a subsequent manufacturing process.

While the present inventive concept has been shown and described with reference to exemplary embodiments thereof, it will be apparent to those of ordinary skill in the art that various changes in form and detail may be made therein without departing 110 from the spirit and scope of the inventive concept.

1. A three-dimensional (3D) semiconductor memory device comprising:
a stack structure comprising a plurality of gate patterns and a plurality of insulating patterns which are alternately and repeatedly stacked on a substrate;
a channel structure penetrating the stack structure and connected to the substrate; and
a vertical insulator comprising a high-k dielectric layer, the vertical insulator covered by the channel structure, wherein the high-k dielectric pattern is in contact with the plurality of gate patterns.

2. The 3D semiconductor memory device of claim 1, wherein the vertical insulator further comprises a plurality of capping patterns disposed between the high-k dielectric layer and the plurality of insulating patterns, the plurality of capping patterns separated from each other by the plurality of gate patterns.

3. The 3D semiconductor memory device of claim 1, wherein the vertical insulator further comprises a blocking insulating layer disposed on the high-k dielectric layer, a charge storing layer disposed on the blocking insulating layer, and a tunnel insulating layer disposed on the charge storing layer,
and wherein a lower portion of the high-k dielectric layer is not covered by the blocking insulating layer.

4. The 3D semiconductor memory device of claim 3, wherein the channel structure covers the lower portion of the high-k dielectric layer.

5. The 3D semiconductor memory device of claim 3, wherein the high-k dielectric layer includes an aluminum oxide layer, a hafnium oxide layer, a zirconium oxide layer, a tantalum oxide layer, or a titanium oxide layer.

6. The 3D semiconductor memory device of claim 5, wherein the tunnel insulating layer comprises a silicon oxide layer,
wherein the blocking insulating layer includes a silicon oxide layer, and
wherein the charge storing layer comprises a trap insulating layer or a insulating layer comprising conductive nano dots, the trap insulating layer having a energy band gap less than that of the tunnel insulating layer and the blocking insulating layer.

7. The 3D semiconductor memory device of claim 1, wherein the plurality of gate patterns comprises metal nitrides or metal silicides.

8. The 3D semiconductor memory device of claim 1, wherein the channel structure comprises:
a first semiconductor layer covering a sidewall of the vertical insulator opposite to the stack structure; and
a second semiconductor layer being in contact with the substrate and the first semiconductor layer, the second semiconductor layer electrically connecting the first semiconductor layer to the substrate.

9.-15. (canceled)

16. A three-dimensional (3D) semiconductor memory device comprising:
a substrate;
a channel structure extended in a first direction perpendicular to the substrate, the channel structure connected to the substrate;
a vertical insulator comprising a high-k dielectric layer disposed on the channel structure;
a first metal gate pattern and a second metal gate pattern disposed on the high-k dielectric layer, wherein the first and the second metal gate patterns are extended in a second direction parallel to the substrate and are spaced apart from each other in the first direction; and
an insulating pattern disposed between the first and the second metal gate patterns.

17. The 3D semiconductor memory device of claim 16 further comprising a capping pattern disposed between the high-k dielectric layer and the insulating pattern.

18. The 3D semiconductor memory device of claim 16 further comprising a pair of poly-silicon patterns and a silicon oxide pattern disposed between the high-k dielectric layer and the insulating pattern, wherein the silicon oxide pattern are arranged between the pair of poly-silicon patterns in the first direction.

19. The 3D semiconductor memory device of claim 16 further comprising a silicon oxide pattern disposed between the high-k dielectric layer and the insulating pattern.

20. The 3D semiconductor memory device of claim 16 further comprising:
a first silicon oxide pattern disposed among the first metal gate pattern, insulating pattern and the high-k dielectric layer;
a second silicon oxide pattern disposed among the second metal gate pattern, insulating pattern and the high-k dielectric layer; and
a poly-silicon pattern disposed between the insulating pattern and the high-k dielectric layer and disposed between the first and the second silicon oxide patterns.
